(19) United States
(12) Patent Application Publication
(10) Pub. No.: US 2026/0349058 A1
(43) Pub. Date: Nov. 5, 2026

(54) MAGNETIC RESONANCE IMAGING APPARATUS, AND COIL ASSEMBLIES AND COIL ARRAYS THEREFOR

(71) Applicant: THE UNIVERSITY COURT OF THE UNIVERSITY OF GLASGOW, Glasgow Strathclyde (GB)

(72) Inventors: Divya BASKARAN, Glasgow Strathclyde (GB); Shajan GUNAMONY, Glasgow Strathclyde (GB)

(21) Appl. No.: 19/484,807

(22) PCT Filed: May 16, 2024
(86) PCT No.: PCT/EP2024/063581

§ 371 Date: Nov. 14, 2025

(30) Foreign Application Priority Data
May 17, 2023 (GB) 2307320.8

(51) Int. Cl. G01R 33/3415; G01R 33/34

(52) U.S. Cl. CPC G01R 33/3415; G01R 33/34084

(57) ABSTRACT

A coil array for use with a magnetic resonance imaging apparatus that is operable with a permanent magnetic field of 7 T is disclosed. The coil array comprises no more than eight transmitter coils arranged around a central axis of the coil array in first and second circumferential rows that are respectively positioned proximal to the head and neck of a patient when in use and are displaced longitudinally along the central axis with respect to each other. A coil assembly for use with a magnetic resonance imaging apparatus that is operable with a permanent magnetic field of 7 T is also disclosed. The coil assembly comprises the disclosed coil array and a receiver coil array. A magnetic resonance imaging apparatus that is operable with a permanent magnetic field of 7 T is disclosed. Said apparatus comprises the disclosed coil assembly.

### FIELD OF THE INVENTION

The present invention relates to a novel transmitter coil configuration suitable for use in a magnetic resonance imaging (MRI) apparatus to simultaneously image both the brain and spinal cord in 7T MRI scanners.

### BACKGROUND

Early detection and diagnosis of brain and spinal cord pathology is crucial to facilitate early treatment and can therefor significantly improve patient outcomes, both in terms of morbidity and mortality rates.

There are many pathologies that affect both the brain and the spinal cord including tumours (including e.g., genetic conditions such as neurofibromatosis and Von-Hippel Lindau disease; metastases, meningiomata, lymphoma, and intrinsic CNS tumours), inflammatory conditions such as multiple sclerosis, transverse myelitis (e.g., neuromyelitis optica), cerebellar neurodegenerative processors, degenerative pathology such as amyotrophic lateral sclerosis and moto neurone disease, vasculitis, rheumatic and auto-immune conditions, trauma and vascular malformations, infections, and metabolic processes such as subacute combined degeneration.

There is therefore a need to concurrently image the anatomy of both the brain and spinal cord—i.e., there is a need for simultaneous brain-cord imaging in medical settings.

Such simultaneous brain-cord imaging has been implemented successfully in magnetic resonance imaging (MRI) scanners (hereinafter referred to interchangeably and synonymously as an ‘MRI apparatus’ or ‘MRI machine’) that operate with a static field of 1.5 and/or 3T. However, the performance of such systems is not necessarily adequate for detecting the small (e.g. sub-mm scale) lesions that can be indicative of pathological characteristics in the brain and spinal cord. In particular, the resolution of 1.5 and 3 T machines may not be sufficient for accurate and repeatable identification of sub-mm lesions.

For example, 1.5 and 3 T MRI machines are not adequate for certain vascular imaging including the assessment of neck vessels (e.g., the carotid and vertebral arteries) and intracranial circulation at the level of the Circle of Willis for pathologies, such as stroke (including stroke secondary to atherosclerosis and/or dissection) or intracranial haemorrhaging.

To be able to detect sub-mm scale lesions it is often necessary to use so-called ultra-field MRI where the static field of the MRI scanner is more than twice as large at—according to industry standard—7T. However, the imaging field-of-view that must be achieved to enable concurrent brain-cord MRI is obviously much larger compared to brain-only or cord-only MRI scans. In the 7T industry-standard MRI scanners, the typical operating frequency for the radio-frequency probe is around 300 MHz (e.g., 298 MHz). The wavelength of such a probe is consequently around 10 cm (e.g., around 12 cm for an operating frequency of 298 MHz). When probing such a large field-of-view with an approximately 300 MHz interrogation signal, the constructive and destructive interference between the electromagnetic waves produced by these radio-frequency probes results in a highly inhomogeneous level of quality across the scanned MRI image, which can be detrimental for the diagnostic value of a scan.

The present invention has been devised in light of the above considerations.

### SUMMARY OF THE INVENTION

The invention is set out in the appended set of claims.

In a general sense, the present invention provides a coil array and coil assembly for use in an industry-standard 7T-MRI apparatus that includes no more than eight transmitter coils arranged in first and second rows that are positioned to respectively image the brain and spinal cord of a patient when in use within an MRI apparatus. The arrangement provided by the present invention enables simultaneous brain-cord MRI without suffering from the parasitic effects of interferences that typically accompany imaging with such large fields-of-view in 7T MRI machines. Further, by providing the (transmitter) coil array with no more than eight transmitter coils, it is possible to easily fit the coil array, and corresponding coil assembly, to pre-existing industry-standard MRI machines thereby reducing the cost and complexity associated with the installation and use of the coil arrays and assemblies of the present invention.

In a first aspect, there is provided a coil array for use with a magnetic resonance imaging apparatus that is operable with a permanent magnetic field of 7T. The coil array comprises no more than eight transmitter coils disposed on a cylindrical support extending around a central axis. The transmitter coils comprise a first coil set arranged in a first circumferential row and a second coil set that is offset from the first coil set in a longitudinal direction that runs parallel to the central axis. The second coil set may be arranged in a second circumferential row, whereby the first circumferential row is offset from the second circumferential row in the longitudinal direction. With this arrangement, the first coil set and the second coil set can be configured for alignment respectively with the head and neck of a patient. The transmitter coils are preferably configured for parallel transmission. The second coil set may comprise a plurality of coils (e.g. two coils) spaced from each other in either the circumferential direction or the longitudinal direction.

As discussed above, a coil array having this configuration is particularly advantageous because it facilitates simultaneous brain-cord imaging using a MRI apparatus and, because it uses no more than eight transmitter coils—which is the industry-standard for MRI machines in commercial, research, and medical settings—the coil array of the first aspect is easily connectable to and useable with pre-existing MRI machines. This makes the coil array of the first aspect both easy and cost-effective to use as it does not require specialist machining to be able to fit the coil array to a pre-existing MRI apparatus or, even more costly, the commissioning of entirely new MRI machines having a bespoke number of transmitter coil connections.

In some embodiments, six transmitter coils may be arranged in the first circumferential row, and two transmitter coils may be arranged in the second circumferential row.

This particular arrangement of transmitter coils in the coil array may be particularly effective at providing high-quality simultaneous brain-cord imaging in MRI contexts. As will be discussed in further detail below, an arrangement of six transmitter coils to deliver MRI interrogation signals to the head of a patient, and two transmitter coils to deliver MRI interrogation signals to the neck of patient may result in final obtained image that simultaneously achieves a sufficiently large field-of-view to be able to determine details of the brain and spinal cord of the patient whilst a corresponding receiver coil array is able to receive the interrogation signals with sufficient resolution to be able to image and identify the small lesions that may be indicative of a range of neurological conditions including multiple sclerosis, amyotrophic lateral sclerosis, and Alzheimer's disease, amongst others. These interrogation signals are typically rapidly oscillating magnetic fields (e.g., with a frequency of around 300 MHz) that are generated by corresponding alternating currents passing through the transmitter coils.

For example, it has been determined that by implementing configurations such as those disclosed herein using the Duke model (see below) with six transmitter coils in the first circumferential row driven in a circularly polarised mode, transmission efficiencies on the order of 30 to 60 nT/V may be achieved. This is comparable to the efficiencies that are achievable with the typical configuration of eight transmitter coils arranged for head/brain measurements that may be found in conventional MRI coil assemblies.

In some embodiments, the first and second circumferential rows may have a longitudinal overlap along the central axis.

This overlap may be beneficial because it can ensure that the transmitter coils in the first and second circumferential rows effectively decouple their transmission signals between the first and second rows. In this way, the detrimental effects associated with interference between rows of coils in large field-of-view imaging can be mitigated and, in some implementations, even completely eliminated.

The overlap between the coils may, for example, be a so-called critical overlap that is selected to eliminate interference between the rows of coils by cancelling the mutual inductance between the coils. The extent of overlap required to achieve this critical overlap may be chosen based on the size and dimensions of the coils being overlapped.

In some embodiments, a plurality of the transmitter coils may be arranged in the first circumferential row to fully encircle the central axis.

In this way, it may be possible to obtain a complete 360 degree image of the brain of a patient when the coil array is used in an MRI apparatus.

In some embodiments, a plurality of the transmitter coils may be arranged in the first circumferential row symmetrically around the central axis. For example, the transmitter coils in the first circumferential row may exhibit rotational symmetry about the central axis. The order of rotational symmetry may correspond to (i.e. be the same as) the number of transmitter coils in the first circumferential row.

A symmetric arrangement of the transmitter coils around the first circumferential row may be particularly beneficial because it facilitates a homogeneous and symmetric probe of the head of the patient by the MRI interrogation signals transmitted by the transmitter coils in the first circumferential row.

In some embodiments, the plurality of transmitter coils arranged in the first circumferential row may not overlap with one another.

In this way, a complete coverage of the field-of-view of the first circumferential row (i.e., the head/brain of the patient) may be achieved with smaller coils because there is no space in the first circumferential row covered by more than one transmitter coil. This may reduce the cost and complexity associated with the manufacture of the first circumferential row of transmitter coils.

In some examples where the coils within the first circumferential row do not overlap, adjacent coils may be effectively decoupled using the so-called transformer decoupling technique. This is achieved by winding the inductors in opposite direction to cancel out the mutual coupling between adjacent coils. This decoupling technique may be preferable to overlapping coils within the first circumferential because overlapping adjacent coils would bring second-neighbour coils closer to one another, thereby increasing the amount of coupling between second-neighbour coils.

In some examples, each of the transmitter coils within the first circumferential row may be identical.

In some examples, the transmitter coils may be spaced equidistantly axially around the central axis. For example, if there are six transmitter coils in the first circumferential row, the centres of each of the transmitter coils may be separated by an angle of approximately 60°.

In some examples, each of the transmitter coils in the first circumferential row may be rectangular coils. For example, the transmitter coils may be rectangular coils each having a length extending in the longitudinal direction parallel to the central axis and a width extending in the axial direction around the central axis.

The length of the transmitter coils in the first circumferential row may be 250 mm or less, 240 mm or less, 230 mm or less, 220 mm or less, 210 mm or less, 200 mm or less, 190 mm or less, 180 mm or less, 170 mm or less, 160 mm or less, or 150 mm or less.

Conversely, the length of the transmitter coils in the first circumferential row may be 150 mm or more, 160 mm or more, 170 mm or more, 180 mm or more, 190 mm or more, 200 mm or more, 210 mm or more, 220 mm or more, 230 mm or more, 240 mm or more, or 250 mm or more.

The length of the transmitter coils may be between 150 mm and 250 mm or between any of the identified values in the preceding lists.

In some examples, the length of each of the transmitter coils in the first circumferential row may be 210 mm.

The width of the transmitter coils in the first circumferential row may be 200 mm or less, 190 mm or less, 180 mm or less, 170 mm or less, 160 mm or less, 150 mm or less, 140 mm or less, 130 mm or less, 120 mm or less, 110 mm or less, or 100 mm or less.

Conversely, the width of the transmitter coils in the first circumferential row may be 100 mm or more, 110 mm or more, 120 mm or more, 130 mm or more, 140 mm or more, 150 mm or more, 160 mm or more, 170 mm or more, 180 mm or more, 190 mm or more, or 200 mm or more.

The width of the transmitter coils may be between 100 mm and 200 mm or between any of the identified values in the preceding lists.

In some examples, the width of the transmitter coils in the first circumferential row may be 140 mm.

In some examples, each of the transmitter coils may be defined by a rectangle having a length of 210 mm and a width of 140 mm.

In examples where the transmitter coils in the first circumferential row do not overlap, adjacent coils may be separated by a distance in the range of 5 to 15 mm, or in some preferred examples by a distance in the range of 10 to 12 mm.

In some embodiments, a plurality of transmitter coils may be arranged in the second circumferential row to partially encircle the central axis.

For example, the plurality of transmitter coils arranged in the second circumferential row define an arc that subtends an angle from the central axis. The subtended angle may, for example, be 120 degrees or less, 110 degrees or less, 100 degrees or less, 90 degrees or less, 80 degrees or less, 70 degrees or less, or 60 degrees or less. The subtended angle may be between 60 and 120 degrees or between any of the identified values in the preceding list.

In some embodiments, the plurality of transmitter coils may be arranged in the second circumferential row to define an approximately semi-circular arc around the central axis.

In other words, some embodiments may encircle half of the neck of the patient in use. Preferable, the half of the neck encircled by the transmitter coils of the second circumferential row is the back half of the neck, proximal to the spinal cord of the patient.

It has been determined, as will be discussed in further detail below, that it is not necessary to fully encircle the neck of a patient to obtain high-quality and informative images of the spinal cord using MRI techniques. A half-encircling via a semi-circular arc defined by the transmitter coils of the second circumferential row may be sufficient facilitate the collection of high-quality images of the patient's spinal cord using MRI techniques.

In some embodiments, a plurality of the transmitter coils may be arranged in the second circumferential row symmetrically about a plane bisecting the first and second circumferential rows along the central axis.

A symmetric arrangement of the transmitter coils around the second circumferential row may be particularly beneficial because it facilitates a homogeneous and symmetric probe of the spinal cord of the patient by the MRI interrogation signals transmitted by the transmitter coils in the second circumferential row.

For example, in the case of two transmitter coils being arranged in the second circumferential row to define a semi-circular arc that partially encircles the neck of the patient when in use, each of the transmitter coils may symmetrically define a quarter-circular arc either side of a plane whose normal is perpendicular to the central axis.

In some embodiments, the plurality of transmitter coils arranged in the second circumferential row may not overlap with one another.

In this way, a complete coverage of the field-of-view of the second circumferential row (i.e., the neck/spinal cord of the patient) may be achieved with smaller coils because there is no space in the second circumferential row covered by more than one transmitter coil. This may reduce the cost and complexity associated with the manufacture of the second circumferential row of transmitter coils.

Additionally, with such an arrangement, the coils in the second row may have a transceiver functionality. The coils in the second circumferential row are significantly larger than typical receiver coils and therefore provide the eventually obtained image with greater signal to noise ratio at the centre of the brain than would be achievable with just conventional smaller receiver coils.

In some examples, all of the coils in both the first and second rows may have a transceiver functionality. The coils in both the first and second circumferential rows are larger than typical receiver coils and therefore provide the eventually obtained image with greater signal to noise ratio at the centre of the brain than would be achievable with just conventional smaller receiver coils.

Adding receiver functionality to the transmit elements can improve the ultimate intrinsic signal-to-noise (SNR) ratio, especially in the centre of the brain region. The inventors have found that the SNR at the centre of the brain obtained using the neurovascular coil arrangement disclosed herein is 14.1% higher than a conventional head coil in which the coils are not configured as transceiver.

In some examples, each of the transmitter coils within the second circumferential row may be identical.

In some examples, the transmitter coils may be separated symmetrically about a plane passing through the central axis. For example, if there are two transmitter coils in the second circumferential row, the transmitter coils may be arranged on either side of the plane.

In some examples, each of the transmitter coils in the second circumferential row may be rectangular coils. For example, the transmitter coils may be rectangular coils each having a length extending in the longitudinal direction parallel to the central axis and a width extending in the axial direction around the central axis.

The length of the transmitter coils in the second circumferential row may be 180 mm or less, 170 mm or less, 160 mm or less, 150 mm or less, 140 mm or less, 130 mm or less, 120 mm or less, 110 mm or less, 100 mm or less, 90 mm or less, or 80 mm or less.

Conversely, the length of the transmitter coils in the second circumferential row may be 80 mm or more, 90 mm or more, 100 mm or more, 110 mm or more, 120 mm or more, 130 mm or more, 140 mm or more, 150 mm or more, 160 mm or more, 170 mm or more, or 180 mm or more.

The length of the transmitter coils in the second circumferential row may be between 80 mm and 180 mm or between any of the identified values in the preceding lists. For example, the length of the transmitter coils in the second circumferential row may be between 100 mm and 160 mm.

In some examples, the length of the transmitter coils may be 100 mm, 110 mm, 120 mm, 130 mm, 140 mm, 150 mm, or 160 mm.

The width of the transmitter coils in the second circumferential row may be 300 mm or less, 290 mm or less, 280 mm or less, 270 mm or less, 260 mm or less, 250 mm or less, 240 mm or less, 230 mm or less, 220 mm or less, 210 mm or less, or 200 mm or less.

Conversely, the width of the transmitter coils in the second axial ow may be 200 mm or more, 210 mm or more, 220 mm or more, 230 mm or more, 240 mm or more, 250 mm or more, 260 mm or more, 270 mm or more, 280 mm or more, 290 mm or more, or 300 mm or more.

The width of the transmitter coils in the second circumferential row may be between 200 mm and 300 mm or between any of the identified values in the preceding lists. For example, the width of the transmitter coils in the second circumferential row may be between 230 mm and 270 mm.

In some examples, the width of the transmitter coils may be 230 mm, 240 mm, 250 mm, 260 mm, or 270 mm.

The length and width of the transmitter coils in the second circumferential row may be independently selected from any of the lists provided above.

In some examples, the transmitter coils arranged in the second circumferential row may be configured to transmit MRI interrogation signals with a phase difference of 45 degrees or more, 60 degrees or more, 90 degrees or more, 120 degrees or more, or 135 degrees or more, 150 degrees or more, or 180 degrees or more between the MRI interrogation signals transmitted by adjacent transmitter coils. In one particular example, using circularly polarized modes for the transmitter coils in the second row, the phase values of the signals transmitted by the transmitter coils in the second circumferential row may be 72 and 216 degrees respectively, corresponding to a phase difference of 144 degrees.

Conversely, the transmitter coils arranged in the second circumferential row may be configured to transmit MRI interrogation signals with a phase difference of 135 degrees or less, 120 degrees or less, 90 degrees or less, 60 degrees or less, or 45 degrees or less between the MRI interrogation signals transmitted by adjacent transmitter coils.

In some examples, the phase difference between the MRI interrogation signals transmitted by adjacent transmitter coils may be between 45 and 135 degrees, or between any of the identified values in the preceding lists.

In some examples, the phase difference between the MRI interrogation signals transmitted by adjacent transmitter coils may be approximately 90 degrees.

In examples where the transmitter coils in the second circumferential row do not overlap, adjacent coils may be separated by a distance in the range of 5 to 15 mm, or in some preferred examples by a distance in the range of 10 to 12 mm.

In some embodiments, one or more of the transmitter coils may be transceiver coils.

In the context of a MRI apparatus, both transmitter and receiver coils are required—the transmitter coils transmit MRI interrogation signals through the body (e.g., the head and spinal cord) of the patient, and the receiver coils receive the MRI interrogation signals after they have interacted with nuclei in the cells of the patient in the imaged area that have been magnetically aligned by the permanent magnetic field of the MRI apparatus. Providing transceiver functionality has the benefit of increasing the image homogeneity of the eventually captured image. This is because the transmitter coils of the apparatuses disclosed herein are much larger than the conventional receiver coils used in the art and therefore are able to provide greater signal to noise ratio at the centre of the brain.

In a further aspect there is further provided a coil assembly for use with a magnetic resonance imaging apparatus that is operable with a permanent magnetic field of 7T. The coil assembly comprises a transmitter coil array as described herein, and a receiver coil array.

A coil assembly comprising a transmitter coil array in accordance with the first aspect of the present invention may be particularly useful as it may be removably connectable with a pre-existing industry-standard 7T MRI apparatus. As discussed above, such a coil assembly is therefore both easy and cost-effective to deploy in contemporary industry-standard 7T MRI machines.

In some embodiments, the transmitter coil array may be enclosed between coaxial inner and outer walls.

These surrounding walls may serve the purpose of protecting the sensitive and fragile transmitter coils from physical damage that could occur if they were handled directly by an operator. By providing substantially cylindrical coaxial inner and outer walls, the coil assembly may be conveniently shaped for easy insertion into the cylindrical chamber of a MRI apparatus. In some contexts, the coaxial geometry of the inner and outer walls may be equivalently referred to as a concentric geometry.

In some examples, the inner and outer walls may be preferably made from a non-magnetic (including non-paramagnetic) material so that they are unaffected by the 7T magnetic field generated by the MRI machine in use. For example, the inner and outer walls may be made from a material that exhibits no ferromagnetic, anti-ferromagnetic, ferrimagnetic, or paramagnetic effects under the application of a magnetic field.

For example, the inner and outer walls of the coil assembly may be made from fibreglass and/or glass reinforced plastic. Such materials are beneficial because they do not exhibit any of the magnetic effects listed above, and are easy to clean, thereby ensuring the sterility of the environment in which the coil assembly is deployed. This may be particularly desirable in medical settings such as hospital-based MRI scanners.

In some embodiments, the coil assembly may further comprise a radio-frequency shield disposed on an inner surface of the outer wall.

In this way, the shielding may prevent external electromagnetic radiation from distorting the MRI interrogation signal and also prevents electromagnetic radiation generated by the MRI apparatus from causing interference with nearby electronic devices. This shielding may be particularly important in medical settings where the proper functioning of electronic equipment such as monitors and scanners is critically important.

In some examples, the RF shield may be made of copper, galvanised steel and/or aluminium or another suitable material (e.g., any metal).

Receiver coils of the receiver coil array may be disposed in the correct location to optimise the detection and processing of the MRI interrogation signal that is transmitted through the patient by the plurality of transmitter coils when the MRI apparatus is in use.

In some embodiments, the receiver coil array may comprise 48 receiver coils arranged in a posterior section of the receiver coil array, and 16 receiver coils arranged in an anterior section of the receiver coil array. The posterior and anterior sections of the receiver coil array respectively correspond to the rear and front of a patient when the receiver coil array is in use.

In this way, it can be ensured that there is a homogeneous or near-homogeneous coverage of the field of view so that any transmitted MRI interrogation signal that interacts with the magnetically activated nuclei in the patient's body are reliably detected.

In some embodiments, the transmitter coils of the transmitter coil array may be transceiver coils, and the receiver coil array may comprise 40 receiver coils arranged in the posterior section of the receiver coil array, and 16 receiver coils arranged in the anterior section of the receiver coil array.

In some examples, the coil assembly may comprise one or more cut-out portions cut out from the coil assembly, e.g., cut-out portions cut through the coil assembly housing defined by the inner and outer coaxial walls of the coil assembly. For example, the cut-outs may define an eyehole or eyeholes for the patient's comfort so that they do not feel too enclosed or claustrophobic during an MRI scan using this coil assembly.

Providing transceiver functionality has the benefit of increasing the image homogeneity of the eventually captured image. This is because the transmitter coils of the apparatuses disclosed herein are much larger than the conventional receiver coils used in the art and therefore are able to provide greater signal to noise ratio at the centre of the brain.

In some examples, the receiver coil array may be located primarily beneath the patient when in use in an MRI apparatus.

In a further aspect, there is provided a magnetic resonance imaging apparatus that is operable with a permanent magnetic field of 7T. The apparatus comprises the coil assembly as described herein.

An MRI apparatus according to this aspect may be particularly beneficial because it achieves both the large field-of-view required for simultaneous brain-cord imaging with the sensitivity associated with 7T MRI machines that is needed to detect and identify the small lesions that may be indicative of a range of neurological conditions including multiple sclerosis, amyotrophic lateral sclerosis, and Alzheimer's disease, amongst others.

In some embodiments, the coil assembly may be removably connectable with the magnetic resonance imaging apparatus.

It may be preferable for the coil assembly described herein to be a removable insert that can be deployed in a 7T MRI machine so that it can be used only when a simultaneous brain-cord scan is required, leaving the MRI apparatus available for other types of scans when simultaneous brain-cord (or just-brain or just-cord) imaging is required.

In some examples, the coil assembly may be removably connectable with the MRI apparatus via one or more connection leads. For example, the transmitter coil array of the coil assembly may be connected to the MRI apparatus via an 8-port Tx (transmitter) connection lead. Similarly the receiver coil array of the coil assembly may be connected to the MRI apparatus via a 64-port Rx (receiver) connection lead. In cases where the transmitter coil array comprises transceiver coils as opposed to transmitter-only coils, the transmitter coil array of the coil assembly may be connected to the MRI apparatus via an 8-port TxRx (transceiver) connection lead. In such a case there may only be 56 receiver-only coils in the receiver coil assembly and so the receiver coil assembly may be connected to the MRI apparatus via a 56-port Rx connection lead.

The invention includes the combination of the aspects and preferred features described except where such a combination is clearly impermissible or expressly avoided.

### SUMMARY OF THE FIGURES

Embodiments and experiments illustrating the principles of the invention will now be discussed with reference to the accompanying figures in which:

FIG. 1a shows a three-dimensional schematic in perspective view of a complete coil assembly for use with a 7T MRI apparatus.

FIG. 1b shows a side view of a transceiver coil array of the coil assembly of FIG. 1a with transmit and receive plugs visible.

FIG. 2 shows a schematic of six transmitter coils arranged in a first circumferential row of a coil array for use with a 7T MRI apparatus.

FIG. 3a shows B₁⁺ field distribution in the sagittal midplane of the industry-standard Duke model for transmitter coils arranged as a conventional 8-channel head coil.

FIG. 3b shows B₁⁺ field distribution in the sagittal midplane of the industry-standard Duke model for transmitter coils arranged as the 6-channel head coil of FIG. 2.

FIGS. 4a-c show exemplary arrangements of two transmitter coils in the second circumferential row of a coil array for use with a 7T MRI apparatus.

FIGS. 5a-c respectively show data illustrating the performance of the transmitter coil arrangements of FIGS. 4a-c on a head-and-shoulder phantom.

FIGS. 6a-c show the B₁⁺ field distribution in the sagittal and axial midplanes of the industry-standard Duke model for transmitter coils in the second circumferential row in the arrangement depicted in FIG. 4a for varying coil widths.

FIGS. 7a-d show the B₁⁺ field distribution in the sagittal and coronal midplanes of the industry-standard Duke model for transmitter coils in the second circumferential row in the arrangement depicted in FIG. 4a for varying coil lengths.

FIG. 8 a shows a schematic of an overall transmit/transceiver coil array for use with a 7T MRI apparatus.

FIG. 8b shows a receiver coil array suitable for use with the transceiver coil array of FIG. 8a.

FIGS. 9a-h show the measured reflection coefficients for each of coils 1 to 8 as labelled in FIG. 8a.

FIGS. 10a-m show the measured coupling between adjacent coils in the coil array shown in FIG. 8a.

FIGS. 11a-j shows the measured coupling between second neighbouring coils in the coil array shown in FIG. 8a.

FIG. 12 shows simulated and measured B₁⁺ maps in a head and shoulder phantom in the sagittal midplane for various operational configurations of the coil array shown in FIG. 8a.

FIG. 13 shows a fast turbo spin echo (TSE) image taken using the coil array shown in FIG. 8a.

FIGS. 14a and 14b shows in-vivo magnetic resonance images collected using the complete coil assembly disclosed herein with reference to FIGS. 1a, 1b, 8a and 8b with labelling of the vertebrae of the C-spine.

FIG. 15 shows schematics of the transceiver elements in (A) the top row and (B) the bottom row of the transmitter coil array of FIG. 8a.

### DETAILED DESCRIPTION OF THE INVENTION

Aspects and embodiments of the present invention will now be discussed with reference to the accompanying figures. Further aspects and embodiments will be apparent to those skilled in the art. All documents mentioned in this text are incorporated herein by reference.

As discussed above, the present invention relates to coil arrays and coil assemblies for use in MRI machines that are configured to operate with a static magnetic field of 7T. These arrays and assemblies are useable to obtain simultaneous brain-cord images using MRI techniques. Given the application of the coil arrays and assemblies disclosed herein to neurovascular magnetic resonance imaging, the coils may be referred to as ‘neurovascular coils’, the coil arrays as ‘neurovascular coil arrays’ or ‘neurovascular arrays’, and the coil assemblies as ‘neurovascular coil assemblies’or ‘neurovascular assemblies’.

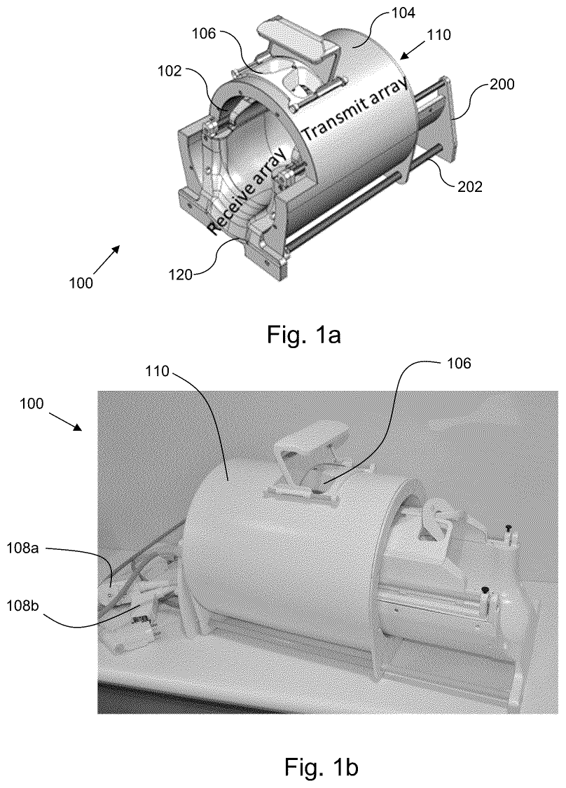

FIG. 1a shows a three-dimensional schematic in perspective view of a neurovascular coil assembly 100 for use with a 7T MRI apparatus 200.

The coil assembly 100 comprises a transmitter coil array 110 and a receiver coil array 120. The coil assembly 100 is shown connected to the MRI machine 200 via rails 202. In this way, it is possible to slide the coil assembly 100 in and out of the central tube (around which the permanent 7T magnet is arranged) of the MRI apparatus. In use, a patient may lie on a bed that is also connected to the rails 202 such that their head and spinal cord are located within the coil assembly 100.

As will be discussed in greater detail below, the transmitter coil array 110 comprises no more than eight, and preferably exactly eight, transmitter, Tx, coils that—in some examples—may be transceiver, TxRx coils. These Tx/TxRx coils are disposed between inner 102 and outer 104 coaxial walls made from a non-magnetic material. As discussed above, a non-magnetic material may be understood as being a material that does not exhibit ferromagnetic, anti-ferromagnetic, ferrimagnetic, or paramagnetic properties. In particular examples, the housing tube defined by the inner 102 and outer 104 coaxial walls may be formed from glass reinforced plastic (GRP) or fibreglass. Disposed between the coaxial walls 102, 104 and preferably between the Tx/TxRx coils and the outer coaxial wall 104, there is disposed a radio frequency (RF) shield that is provided to prevent RF interference between the MRI apparatus 200 and the external environment. As discussed above, the RF shield may be formed from any suitable conductive material (such as any metal). Particular examples may comprise a RF shield formed from copper, galvanised steel, aluminium, or similar. The thickness of the RF shield may be selected by the skilled person to provide an appropriate amount of shielding against interference effects between the MRI apparatus 200 and the external environment. For example, the RF shield may be a slotted RF shield made of two-layer printed circuit boards with an 18 μm thick copper plane. This may be attached to the inner surface of the outer coaxial 104 of the fibre glass housing tube.

For user comfort, the tube housing (i.e., the total housing defined by the inner 102 and outer 104 coaxial walls) may have cut-out portions 106 to define eye slots in front of the eyes of a patient when the coil assembly 100 is used with the 7T MRI apparatus 200. The cut-out portions 106 may be of a size selected by the skilled person to provide a clear view through the transmitter coil array 110 for the patient when the coil assembly 100 is in use. For examples, the cut-out portions may comprise two substantially rectangular cut-outs having dimensions of 70×65 mm².

Although not expanded upon herein, a transmitter coil array of the receiver coil assembly 120 may have a similar physical configuration, in terms of inner and outer walls, and RF shielding as the transmitter coil array 110.

FIG. 1b shows a side view photograph of the transmitter coil array of the coil assembly 100 of FIG. 1a with transmit and receive plugs 108 visible. In the photograph of FIG. 1b, the transmitter coil array 110, and the cut-out portions 106 cut therethrough are clearly visible. Additionally, the coil assembly 100 further comprises first 108a and second 108b connection leads terminating in respective plugs. Said plugs are useable to electrically connect the coil assembly 100 with the overall MRI machine 200. As is standard in the field of 7T MRI machines, the connection leads may provide either: (i) an eight-port transmitter (Tx) coil connection 108 with a corresponding 64-port receiver (Rx) coil connection in the receiver coil array or (ii) an eight-port transceiver (TxRx) coil connection 108 with a corresponding 56-point receiver (Rx) coil connection in the receiver coil array.

The following discussion will explore the simulated and measured performance of the transmitter coil array 110 in various operation modes and physical configurations.

Unless stated otherwise, the simulated performance of the transmitter coil array 110 and the simulated performance of the transmitter coils thereof is based on simulations according to the parameters set out below.

The coils (be they transmitter or transceiver coils) of the transmitter coil array 110 are tuned and matched to a head-shoulder phantom simulated as being filled with a tissue-equivalent solution. This tissue-equivalent solution has a relative permittivity, εᵣ, of 52.1, and a conductivity, σ, of 0.41 S m⁻¹. The coil is then simulated as being loaded with a member of the industry-standard Virtual Family models prepared and maintained by the United States Food & Drug Administration (FDS) in collaboration with the Foundation for Research on Information Technologies in Society (IT'IS Foundation, Zurich, Switzerland); Schmid & Partner Engineering AG (SPEAG, Zurich, Switzerland); the Hospital of the Friedrich-Alexander-University, Erlangen, Germany; and Siemens Medical Solutions, Erlangen, Germany. See the Reference listed below for further details regarding the Virtual Family models. In the context of the present invention, the so-called “Duke” model proposed by Christ et al. was used to simulate the performance of the transmitter coil array 110. The Duke model is a simulated phantom designed to be representative of a typical 34-year-old male. In addition to the detailed results present below, simulations using the Duke model were used to verify effective B₁⁺ shimming and specific absorption rate that are implemented/measured when using the transmitter coil array 110.

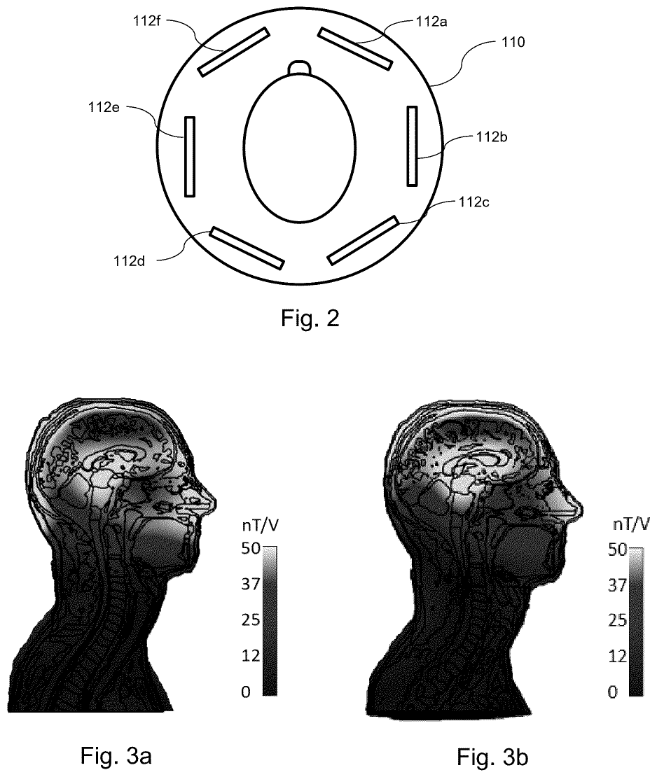

FIG. 2 shows a schematic of six transmitter coils 112a-f arranged in a first circumferential row of the transmitter coil array 110 shown in FIGS. 1a and 1b.

As discussed above, the six transmitter (Tx) coils 112a-f may be transceiver (TxRx) coils—i.e., they may have both transmitter and receiver functionality. As used herein, the term ‘transmitter’ should be considered exchangeable with ‘transceiver’ in all instances apart from those where it would be illogical or physically incompatible.

In cases where the coils 112a-f are transmitter-only coils, the six transmitter coils 112a-f, together with a further two transmitter-only coils in a second circumferential row of the coil array 110 and 64 receiver coils in the receiver coil array 120 define an 8-transmitter-64-receiver (8Tx64Rx) coil assembly 100. Conversely, in cases where the coils 112a-f are transceiver coils with both transmitter and receiver functionality, the six transceiver coils 112a-f, together with a further two transceiver coils in a second circumferential row of the coil array 110 and 56 receiver coils in the receiver coil array 120 define an 8-transceiver-56-receiver (8TxRx56Rx) coil assembly 100.

As can be seen from FIG. 2, the six coils 112a-f arranged in the first circumferential row of the transmitter coil array 110 are preferably arranged symmetrically around the central axis of the coil array 110, with an angular separation of 60 degrees between adjacent coils. The first circumferential row of the transmitter coil array 110 is arranged such that, in use, the six coils 112a-f of said coil array 110 are located in a position that makes them suitable for transmitting MRI interrogation signals through the head of a patient such that corresponding receiver coils in the receiver coil array 120 (and the six coils 112a-f themselves if they are transceiver coils) can detect signals that enable the MRI apparatus 200 to image the brain of the patient.

In a particular example, the six coils 112a-f arranged in the first circumferential row of the transmitter array 110 are substantially identical rectangular coils having a length in the longitudinal direction of the coil array 110 of approximately 210 mm, and a width in the axial direction of the coil array 110 of approximately 140 mm.

The six coils 112a-f, in this and in other embodiments, may comprise a plurality of evenly distributed capacitors having a fixed capacitance, and a variable (or tuning) capacitor for adjusting the frequency of radio waves emitted from the coil. Adjacent capacitors are connected with wire, for example in a preferred example, each pair of adjacent capacitors is connected with silver-plated copper wire having a 2 mm diameter.

In cases where the six coils 112a-f are transceiver coils, each coil preferably includes an in-built transmitter-receiver (TR) switch to switch the coil between transmitter and receiver functionalities.

The six coils 112a-f arranged in the first circumferential row preferably do not overlap with one another. In a preferred example, the separation between adjacent coils 112 a-f is 10 mm.

The six coils 112a-f, when in use, may be configured to operate with a fixed phase difference between each pair of adjacent coils. In a preferred example, the fixed phase difference between adjacent coils 112a-f is 60 degrees.

Conventional prior MRI apparatus have used eight transmitter or transceiver coils to fully encircle the head of a patient in use.

FIG. 3a shows an exemplary B₁⁺ field distribution in the sagittal midplane in the Duke model for transmitter coils arranged in the such a configuration. As is convention, and as used herein, the notation B₁⁺ is used to indicate the relevant subfields of the magnetic fields generated by the transmitter coils 112a-f that are rotating in the same direction as the nuclear precession excited in the nuclei of the patient being imaged by the MRI apparatus 200 by the 7T permanent magnet of said MRI apparatus 200. In cases where the fields generated by the transmitter coils 112a-f are linearly polarised, the magnitude of the B₁⁺ subfield is therefore half the magnitude of the generated field. For this reason, it is preferable to configure the transmitter coils 112a-f with a circular polarisation that rotates in the same direction as the nuclear precession so that the entire generated field is the B₁⁺ subfield.

As a comparison, FIG. 3b shows a simulated B₁⁺ field distribution in the sagittal midplane in the Duke model for transmitter coils arranged as the six-coil head coil arrangement depicted in FIG. 2.

In the context of MRI, the B₁⁺ field distribution for a given transmitter coil array (as a function of voltage) is a measure of the efficiency with which current passing through the coils of the coil array generates a magnetic field therefrom. Consequently, the distribution of magnetic field as a function of voltage can be viewed as a measure of the quality of the MRI achievable with said transmitter coil array.

As can be seen by comparing FIGS. 3a and 3b, the B₁⁺ field distribution achievable in the brain of a patient using the six-coil arrangement exemplified in FIG. 2 is similar to that achieved by a typical eight-coil distribution. In the particular simulation results depicted in FIGS. 3a and 3b, both configurations achieve distribution values in the range 30 to 60 nT V⁻¹ in the region of the brain of the Duke model. In other words, the novel configuration proposed and disclosed herein achieves a similarly efficient generation of magnetic field as the conventional eight-coil configuration. This is particularly beneficial because the reduction of the number of transmitter coils 112a-f in the first circumferential row means that, even in conventional 7T MRI contexts where eight transmitter coils are available, two transmitter coils are still available to be arranged in the second circumferential row to image the spinal cord (and in particular the c-spine) of a patient while the six transmitter coils 112a-f in the first circumferential row simultaneously image the head and brain of the patient.

In addition to the six coils 112a-f arranged in a first circumferential row to image the brain of a patient using MRI techniques, the transmitter coil array 110 further comprises two transmitter coils (or transceiver coils if the six coils 112a-f in the first circumferential row are transceiver coils) arranged in a second circumferential row to simultaneously image the neck and spinal cord of the patient.

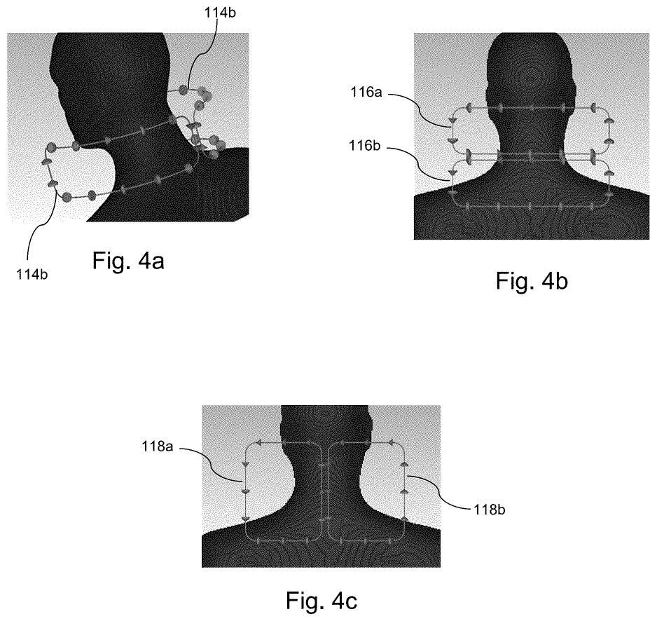

FIG. 4a shows a preferred arrangement of two transmitter coils 114a-b arranged in the second circumferential row of the transmitter coil array 110. In the arrangement shown in FIG. 4a, the two transmitter (or transceiver) coils 114a-b are arranged symmetrically either side of a plane passing through the central axis of the transmitter coil array 110 and extends axially around the transmitter coil array to define a substantially semi-circular arc that partially encircles the neck of the patient (preferably the back half of the neck) when the transmitter coil array 110 is in use. In other words, the two transmitter coils 114a-b curve around from the back of the neck in opposite directions, each coil subtending an angle of approximately 90 degrees about the central axis.

In a particular example, the two coils 114a-b arranged in the second circumferential row of the transmitter array 110 are substantially identical rectangular coils having a length in the longitudinal direction of the coil array 110 between 100 mm and 160 mm, and a width in the axial direction of the coil array 110 between 230 mm and 270 mm.

The two coils 114a-b, in this and in other embodiments, may comprise a plurality of evenly distributed capacitors having a fixed capacitance, and a variable (or tuning) capacitor for adjusting the frequency of radio waves emitted from the coil. Adjacent capacitors are connected with wire, for example in a preferred example, each pair of adjacent capacitors is connected with silver-plated copper wire having a 2 mm diameter.

In cases where the two coils 114a-b are transceiver coils, each coil preferably includes an in-built transmitter-receiver (TR) switch to switch the coil between transmitter and receiver functionalities.

The two coils 114a-b arranged in the second circumferential row preferably do not overlap with one another. In a preferred example, the separation between adjacent coils 114 a-b is 10 mm.

The two coils 114a-b, when in use, may be configured to operate with a fixed phase difference between each pair of adjacent coils. In an example, the fixed phase difference between adjacent coils 114a-b is 90 degrees. In another example, that may be particularly effective, the phase difference between the two adjacent coils 114a-b when operating in the circularly polarised mode may be 144 degrees (with a first coil 114a having a phase of 72 degrees and a second coil 114b having a phase of 216 degrees). With these phase differences, the B₁⁺ field distribution in the neck region of the patient can be maximised without compromising the field distribution in the head region of the patient.

FIG. 4b shows an alternative arrangement of two transmitter coils 116a-b in the second circumferential row of the transmitter coil array 110. In the arrangement shown in FIG. 4b, the two transmitter coils (or transceiver) coils 116a-b are arranged symmetrically either side of a line bisecting the second circumferential row in a direction perpendicular to the central axis of the transmitter coil array 110 and lie flat within the transmitter coil array. In other words, the two transmitter coils 116a-b lie flat under the back of the neck of a patient when in use.

In a particular example, the two coils 116a-b arranged in the second circumferential row of the transmitter array 110 are substantially identical rectangular coils having a length in the longitudinal direction of the coil array 110 between 100 mm and 160 mm, and a width in the axial direction of the coil array 110 between 230 mm and 270 mm.

The two coils 116a-b, in this and in other embodiments, may comprise a plurality of evenly distributed capacitors having a fixed capacitance, and a variable (or tuning) capacitor for adjusting the frequency of radio waves emitted from the coil. Adjacent capacitors are connected with wire, for example in a preferred example, each pair of adjacent capacitors is connected with silver-plated copper wire having a 2 mm diameter.

In cases where the two coils 116a-b are transceiver coils, each coil preferably includes an in-built transmitter-receiver (TR) switch to switch the coil between transmitter and receiver functionalities.

The two coils 116a-barranged in the second circumferential row preferably do not overlap with one another. In a preferred example, the separation between adjacent coils 116a-b is between 10 and 12 mm.

The two coils 116a-b, when in use, may be configured to operate with a fixed phase difference between each pair of adjacent coils. In a preferred example, the fixed phase difference between adjacent coils 116a-b is 90 degrees. With this phase difference, the B₁⁺ field distribution in the neck region of the patient can be maximised without compromising the field distribution in the head region of the patient.

FIG. 4c shows a further alternative arrangement of two transmitter coils 118a-b in the second circumferential row of the transmitter coil array 110. In the arrangement shown in FIG. 4c, the two transmitter coils (or transceiver) coils 118a-b are arranged symmetrically either side of a line bisecting the second circumferential row in a direction parallel to the central axis of the transmitter coil array 110 and lie flat within the transmitter coil array. In other words, the two transmitter coils 118a-b lie flat under the back of the neck of a patient when in use.

In a particular example, the two coils 118a-b arranged in the second circumferential row of the transmitter array 110 are substantially identical rectangular coils having a length in the longitudinal direction of the coil array 110 between 230 mm and 270 mm, and a width in the axial direction of the coil array 110 between 100 mm and 160 mm.

The two coils 118a-b, in this and in other embodiments, may comprise a plurality of evenly distributed capacitors having a fixed capacitance, and a variable (or tuning) capacitor for adjusting the frequency of radio waves emitted from the coil. Adjacent capacitors are connected with wire, for example in a preferred example, each pair of adjacent capacitors is connected with silver-plated copper wire having a 2 mm diameter.

In cases where the two coils 118a-b are transceiver coils, each coil preferably includes an in-built transmitter-receiver (TR) switch to switch the coil between transmitter and receiver functionalities.

The two coils 118a-b arranged in the second circumferential row preferably do not overlap with one another. In a preferred example, the separation between adjacent coils 116a-b is between 10 and 12 mm.

The two coils 118a-b, when in use, may be configured to operate with a fixed phase difference between each pair of adjacent coils. In a preferred example, the fixed phase difference between adjacent coils 116a-b is 90 degrees. With this phase difference, the B₁⁺ field distribution in the neck region of the patient can be maximised without compromising the field distribution in the head region of the patient.

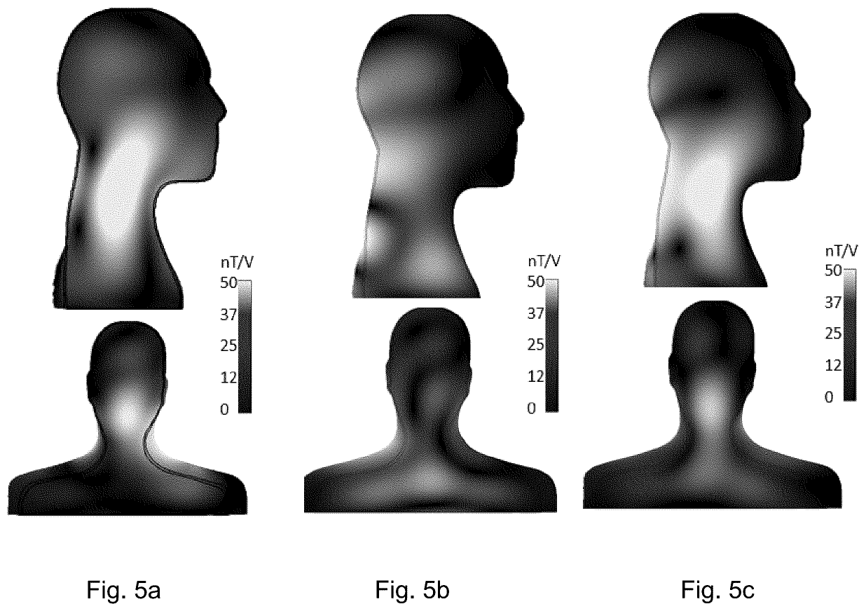

FIGS. 5a-c respectively show data illustrating the performance of the transmitter coil arrangements of FIGS. 4a-c. FIGS. 5a-c show the simulated B₁⁺ field achievable in the sagittal midplane of the head and shoulder phantom described above for the transmitter coils 114a-b, 116a-b, 118a-b arranged as shown in FIGS. 4a-c respectively. In the context of MRI, the greater the magnitude of the magnetic field (a.k.a. magnetic flux density) the higher the quality of the eventually obtained image.

As can be seen from FIGS. 5a-c, the arrangements depicted in FIGS. 4b and 4c achieve magnetic field strengths in the neck region of the patient of 15 to 45 and 30 to 50 nT/V respectively. Meanwhile, the arrangement depicted in FIG. 4a achieves magnetic field strengths in the neck region of the patient of 30 to 60 nT/V. As such, the arrangement depicted in FIG. 4a can be considered to be preferable in view of its demonstrably improved performance relative to other arrangements.

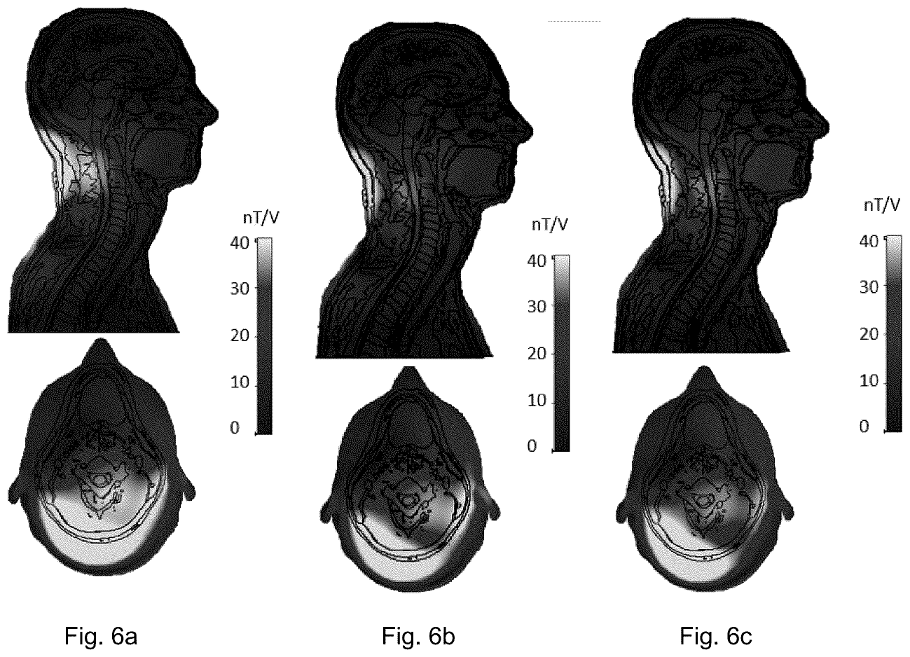

FIGS. 6a-c show exemplary B₁⁺ field distributions in the sagittal and axial midplanes in the Duke model for transmitter coils 114a-bin the second circumferential row in the arrangement depicted in FIG. 4a for varying coil widths.

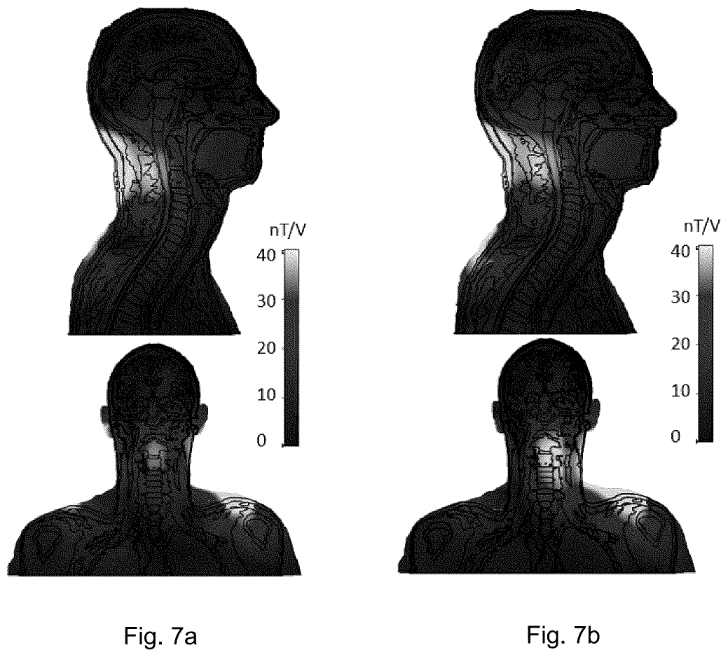

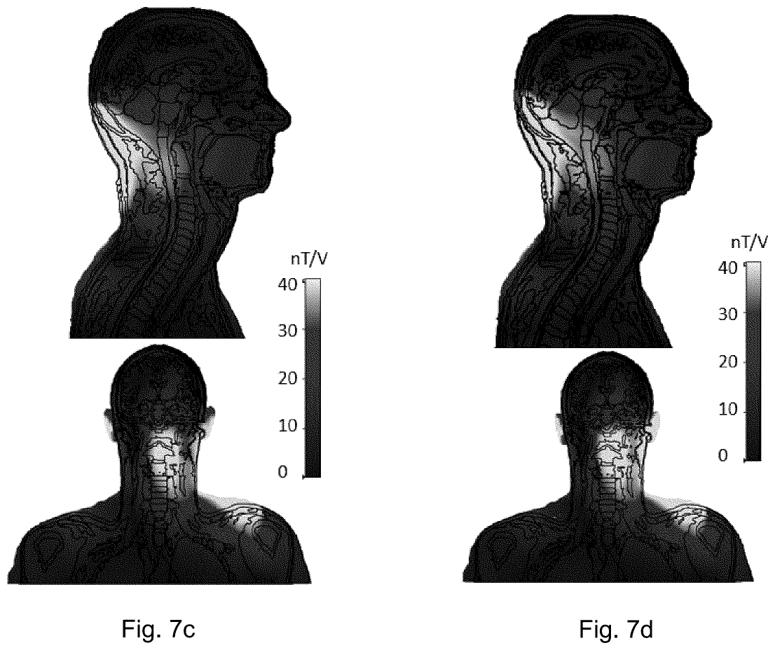

FIGS. 7a-d show exemplary B₁⁺ field distributions in the sagittal and coronal midplanes in the Duke model for transmitter coils 114a-b in the second circumferential row in the arrangement depicted in FIG. 4a for varying coil lengths.

The data shown in FIG. 6a shows the B₁⁺ field distributions in the sagittal and axial planes in the Duke model for transmitter coils 114a-b in the second circumferential row in the arrangement having a length in the longitudinal direction of 100 mm and width in the axial direction of 230 mm.

The data shown in FIG. 6b shows the B₁⁺ field distributions in the sagittal and axial planes in the Duke model for transmitter coils 114a-b in the second circumferential row in the arrangement having a length in the longitudinal direction of 100 mm and width in the axial direction of 250 mm.

The data shown in FIG. 6c shows the B₁⁺ field distributions in the sagittal and axial planes in the Duke model for transmitter coils 114a-b in the second circumferential row in the arrangement having a length in the longitudinal direction of 100 mm and width in the axial direction of 270 mm.

The data shown in FIG. 7a shows the B₁⁺ field distributions in the sagittal and coronal planes in the Duke model for transmitter coils 114a-b in the second circumferential row in the arrangement having a length in the longitudinal direction of 100 mm and width in the axial direction of 230 mm.

The data shown in FIG. 7b shows the B₁⁺ field distributions in the sagittal and coronal planes in the Duke model for transmitter coils 114a-b in the second circumferential row in the arrangement having a length in the longitudinal direction of 120 mm and width in the axial direction of 230 mm.

The data shown in FIG. 7c shows the B₁⁺ field distributions in the sagittal and coronal planes in the Duke model for transmitter coils 114a-b in the second circumferential row in the arrangement having a length in the longitudinal direction of 140 mm and width in the axial direction of 230 mm.

The data shown in FIG. 7d shows the B₁⁺ field distributions in the sagittal and coronal planes in the Duke model for transmitter coils 114a-b in the second circumferential row in the arrangement having a length in the longitudinal direction of 160 mm and width in the axial direction of 230 mm.

In the particular simulation results depicted in FIGS. 6a-c and 7a-d, both configurations achieve distribution values in the range 25 to 50 nT V⁻¹ in the region of the spinal cord (and particularly the c-spine) of the Duke model. This distribution value is sufficient to obtain high-quality images of the c-spine simultaneously with the brain imaging by the six transmitter coils 112a-f of the first circumferential row.

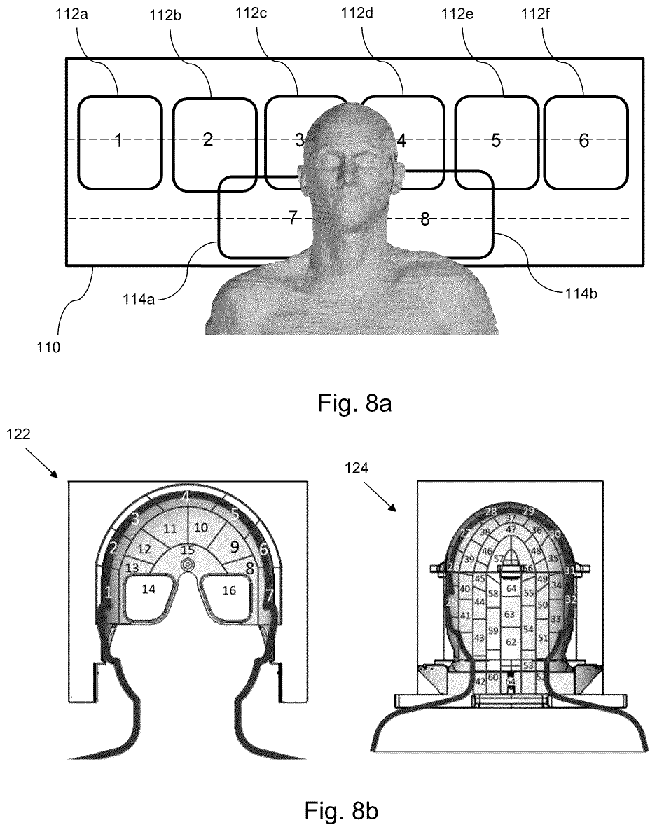

FIG. 8a shows a schematic of an overall transmitter coil array 110 with transmitter coils 112a-f, 114a-b arranged in first and second circumferential rows with the first and second circumferential rows being longitudinally displaced along a central axis of the transmitter coil array 110. For illustrative purposes, the transmitter coil array 110 and constituent transmitter coils 112a-f, 114a-bare depicted ‘unfolded’. In reality, the transmitter coil array would be curved around the head and neck of the depicted phantom to form an enclosing tube, such as is depicted in FIG. 1a.

For the purposes of the following discussion, the transmitter coils 112a-f, 114a-b of the transmitter coil will be numbered. The transmitter coils 112a-f arranged in the first circumferential row may be identified as the first 112a, second 112b, third 112c, fourth 112d, fifth 112e, and sixth 112f transmitter coils. Similarly, the transmitter coils 114a-b arranged in the second circumferential row may be identified as the seventh 114a and eighth 114b transmitter coils.

The transmitter coils 112a-f arranged in the first circumferential row preferably have the arrangement and configuration discussed above in relation to FIG. 2. Meanwhile, the transmitter coils 114a-b arranged in the second circumferential row preferably have the arrangement and configuration discussed above in relation to FIG. 4a.

As can be seen from FIG. 8a, the first and second circumferential rows of transmitter coils have an overlap in the longitudinal direction. The extent of the overlap is preferably selected to optimise decoupling of adjacent coils and may, for example, be 25 mm. Providing such an overlap facilitates the decoupling of the alternating magnetic fields generated by each of the first and second circumferential rows. By decoupling between rows, it is possible to mitigate, or even completely eliminate, the parasitic and detrimental effects of interference between rows. In some examples, the correct extent of overlap may be achieved by implementing conventional shimming methods, possibly in a trial-and-error fashion.

In operation, each of the transmitter coils 112a-f, 114a-b may be operated singly in a single channel (or circularly polarised) operational mode (sTx), or together in a parallel operational mode (pTx). Any combination of the transmitter coils 112a-f, 114a-b may be activated simultaneously or in a predetermined or manually selected sequence.

FIG. 8 b shows an example configuration of a 56 receiver coil array that can be used when the transmitter coil array of FIG. 8a is configured as a transceiver array. An anterior segment 122 of the receiver array has 16 receiver elements arranged in three rows and two eye loops (Rx14 and Rx16). A posterior segment 124 of the receiver array has 40 elements arranged in 5 rows.

The transmit and receive coil arrays discussed above can be constructed in two separate housing segments. The 8-channel transceiver array can be mounted on an outer cylindrical tube, while the 56-channel receiver elements can be mounted on a close tight-fitting helmet. The outer cylindrical tube may be a 2 mm thick rapid prototyped fibreglass tube. A slotted two-layer flexible PCB with a 18 μm thick copper plane can be attached to the inner surface of the outer fiberglass tube for local RF shielding.

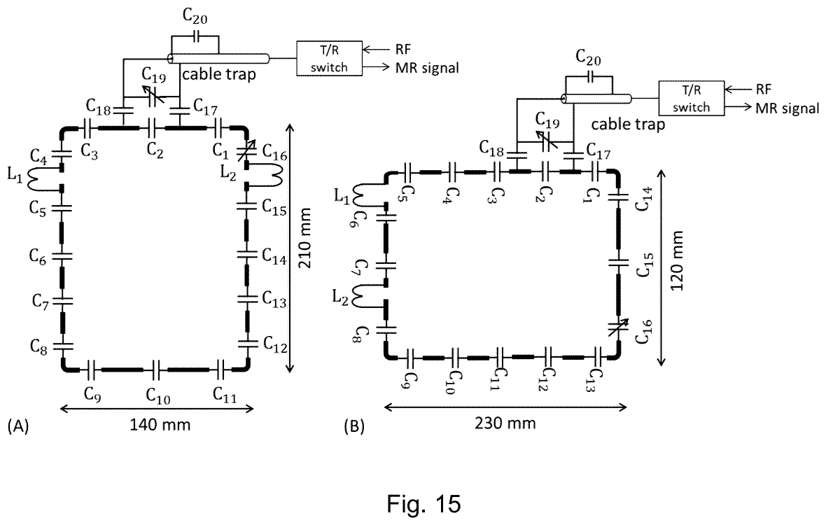

The schematics of the transmit elements in the top and bottom rows are shown in FIG. 15. Each element includes 15 fixed capacitors, C1 to C15 (ATC 100C series), with an average value of 6.2 pF, and two variable capacitors, C16 and C19 (5,610; 1-7.5 pF; Johanson Manufacturing Corporation, NJ, United States), for matching and tuning. The capacitors are distributed evenly on each element and connected with 2 mm diameter silver plated copper wire. The decoupling inductors (L1, L2) in this example are hand-wound using 1.25 mm thick enamelled copper wire (RS PRO, UK). Each channel was connected to TR switches, and the transmit and receive functions were separated by appropriately biasing the pin diodes (MA4P 7446, MACOM, USA) in the switch. A shielded cable trap tuned to 297.2 MHz is used to connect each loop to its respective TR switch. The length of the cable trap and matching capacitor (C2 and C19) were adjusted to achieve the pre-amplifier decoupling in each transceiver loop. The matching capacitor (C2 and C19) is configured to match each element to 50 ohm.

The receiver helmet is designed to be close-fitting and consisted of two compartments—an anterior compartment with 16 receive elements and a posterior compartment with 40 receive elements. The numbering and arrangement of the 56 receive elements in the anterior and posterior segments are shown in FIG. 8b. The dimensions of the posterior helmet were 230 mm and 200 mm in the longitudinal and transverse directions, respectively, which were chosen to accommodate the 5-95 percentiles of the human population. The helmet was 3D-printed using the selective laser sintering technique and painted with bio-compatible paint. To make patient positioning during scanning easier, the transceiver tube and receiver helmet can be slidably mounted on a rod. The anterior segment of the helmet has 16 elements in three rows, with seven, six, and one element in each row, respectively, and two eye loops. The posterior segment of the helmet had 40 elements distributed in five rows with eight, ten, eleven, seven, and four elements in each row. Close to ten receive elements were placed in the neck region. To reduce the mutual coupling between neighbouring elements in the receiver array, a combination of inductive decoupling and geometrical overlap was employed. Non-adjacent elements were decoupled by the preamplifier decoupling technique. Each receive element was tuned to 297.2 MHz using three fixed capacitors of 7.5 pF (ATC 100B series) and one variable capacitor, with 1.2 mm fine silver wire (metal clays 4 you, UK) used to connect the capacitors. A pin-diode-based (MA4P7464, MACOM, USA) LC tank circuit was connected to one of the fixed capacitors in each receive channel to actively detune the receive elements during the RF transmit phase. A secondary safety mechanism, in case of failure of the active detuning circuit, was provided in each receive loop by adding a protection fuse in series. Each receive channel was connected to low-impedance pre-amplifiers by a shielded coaxial trap to suppress the common mode current on the cable, and its length was adjusted for pre-amplifier decoupling. The RF and DC wires and cable traps were routed in such a way as to minimize interference with the transmit coil during the scanning. The 56 channels were divided into two groups—24 channels and 32 channels. The 24 channels were bundled into three 8-pin ODU connectors, and the remaining 32 channels were bundled into a single 32-pin ODU connector.

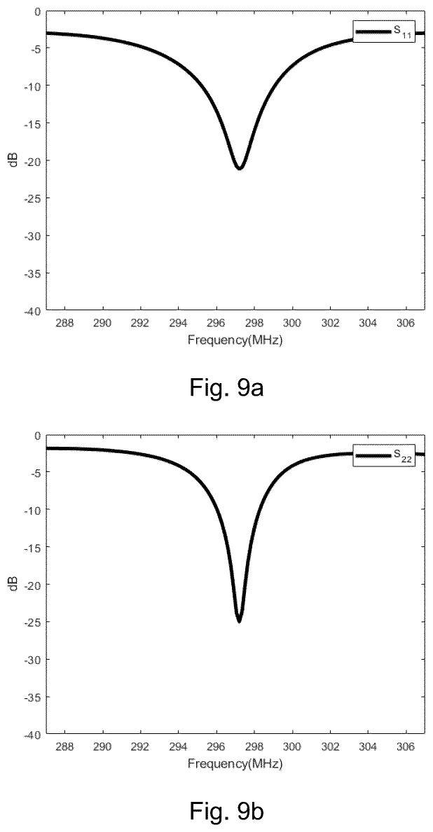

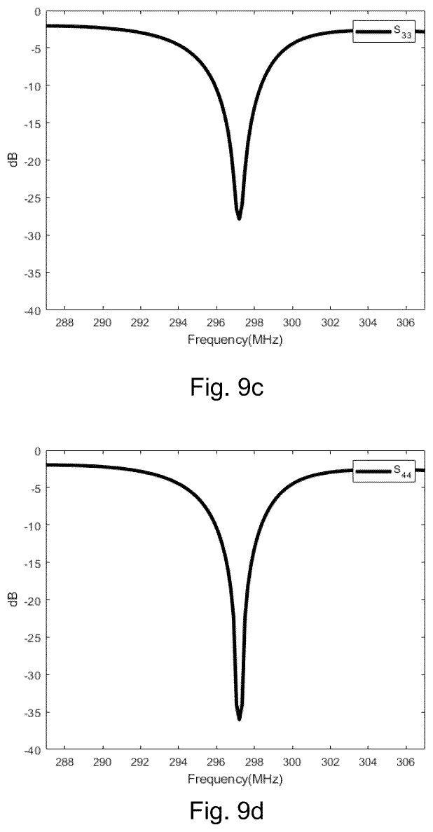

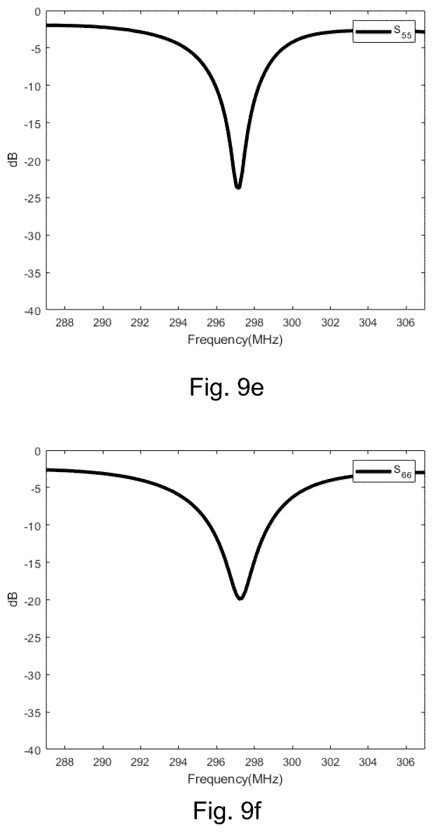

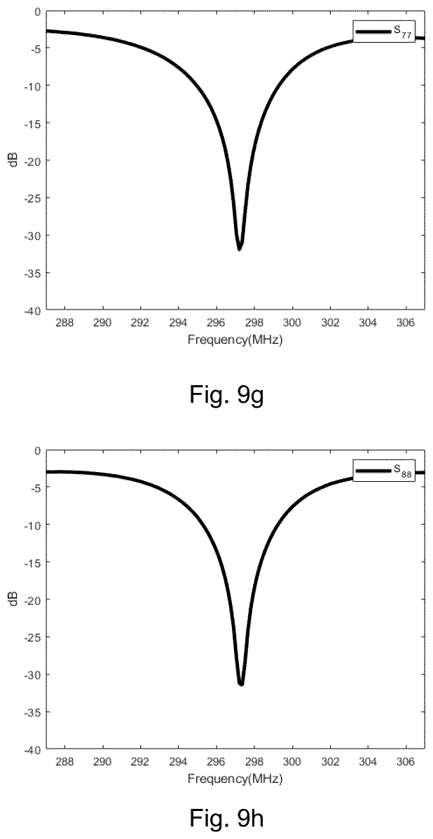

FIGS. 9a-h, 10a-m, and 11a-j show data indicative of the performance of the transmitter coil array 110 of FIG. 8a.

FIGS. 9a-h show the measure reflection coefficients of the channels connected to each of the transmitter coils 112a-f, 114a-b respectively.

FIG. 9a shows a measured power reflection coefficient as a function of frequency of the channel connected to the first transmitter coil 112a.

FIG. 9b shows a measured power reflection coefficient as a function of frequency of the channel connected to the second transmitter coil 112b.

FIG. 9c shows a measured power reflection coefficient as a function of frequency of the channel connected to the third transmitter coil 112c.

FIG. 9d shows a measured power reflection coefficient as a function of frequency of the channel connected to the fourth transmitter coil 112d.

FIG. 9e shows a measured power reflection coefficient as a function of frequency of the channel connected to the fifth transmitter coil 112e.

FIG. 9f shows a measured power reflection coefficient as a function of frequency of the channel connected to the sixth transmitter coil 112f.

FIG. 9g shows a measured power reflection coefficient as a function of frequency of the channel connected to the seventh transmitter coil 114a.

FIG. 9h shows a measured power reflection coefficient as a function of frequency of the channel connected to the eighth transmitter coil 114b.

As can be seen from FIGS. 9a-h, the power reflection coefficient of all elements is less than −25.1 dB, thus indicating that at least 99.7% of the input power is coupled into each element of the transmitter coil array 110.

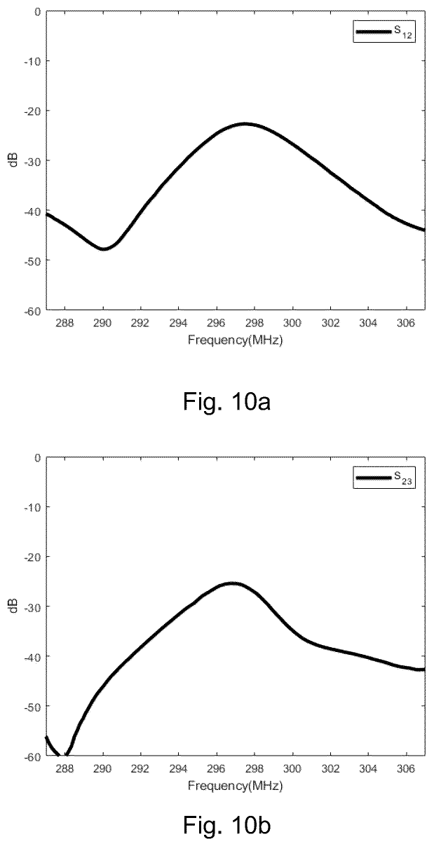

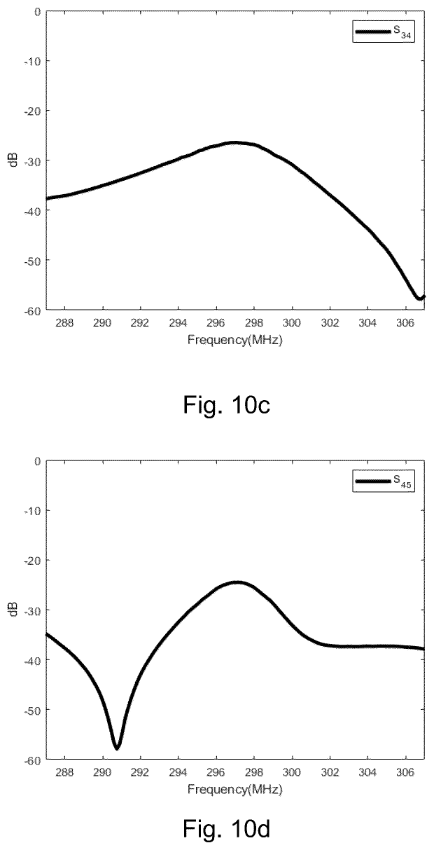

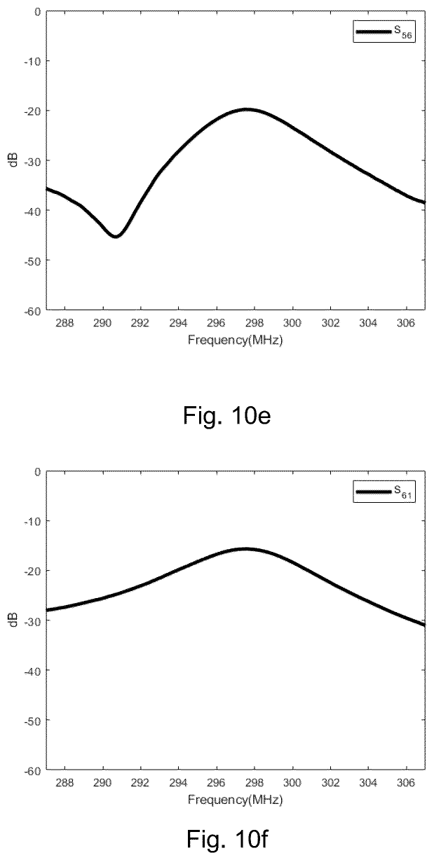

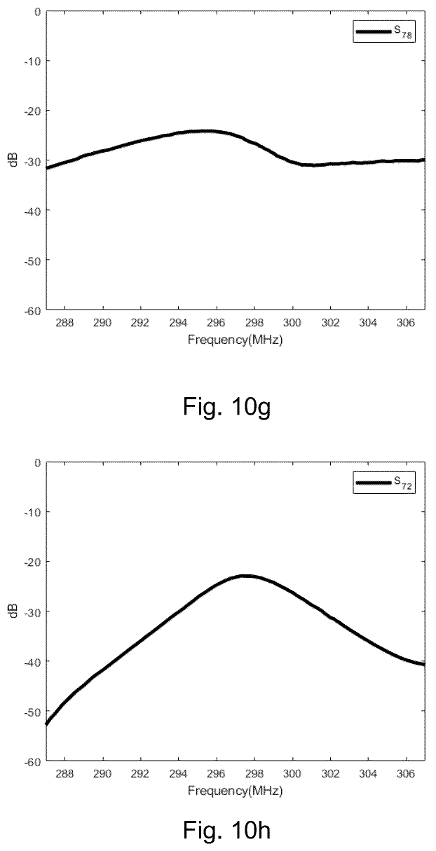

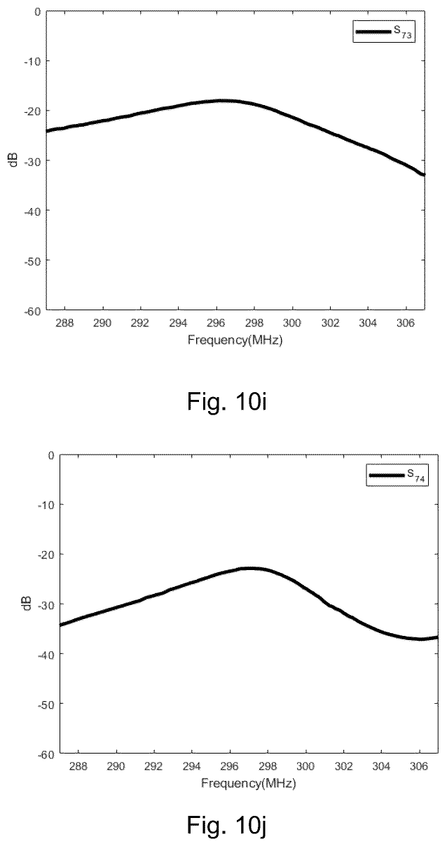

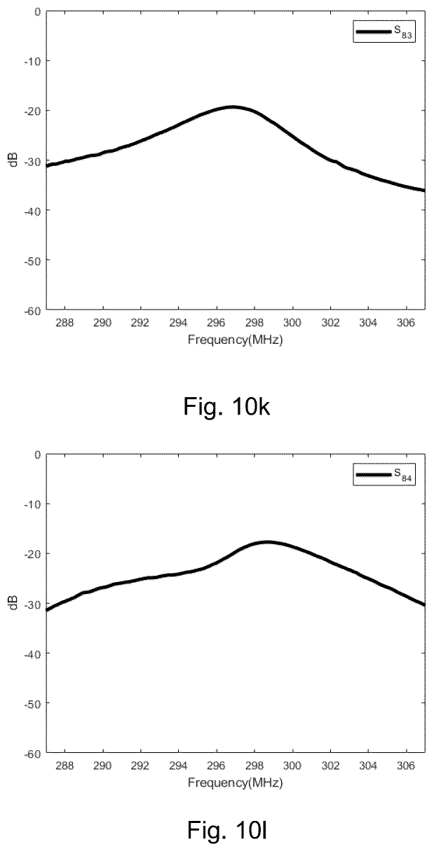

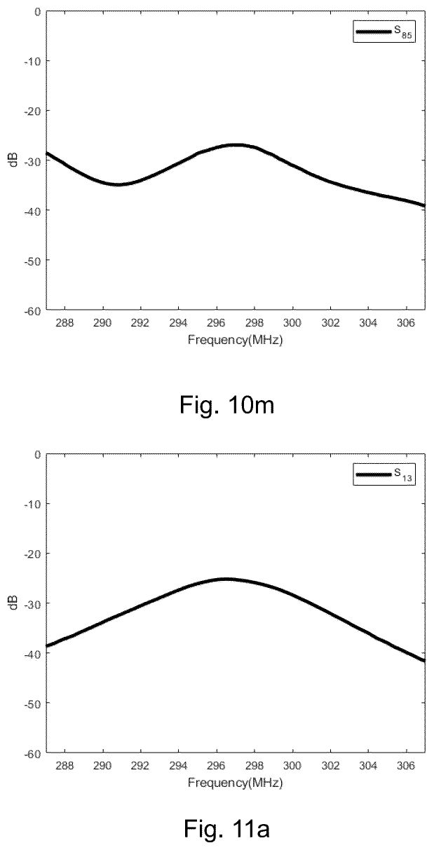

FIG. 10a shows a measured coupling coefficient as a function of frequency between the channels connected to the first 112a and second 112b transmitter coils.

FIG. 10b shows a measured coupling coefficient as a function of frequency between the channels connected to the second 112b and third 112c transmitter coils.

FIG. 10c shows a measured coupling coefficient as a function of frequency between the channels connected to the third 112c and fourth 112d transmitter coils.

FIG. 10d shows a measured coupling coefficient as a function of frequency between the channels connected to the fourth 112d and fifth 112e transmitter coils.

FIG. 10e shows a measured coupling coefficient as a function of frequency between the channels connected to the fifth 112e and sixth 112f transmitter coils.

FIG. 10f shows a measured coupling coefficient as a function of frequency between the channels connected to the sixth 112f and first 112a transmitter coils.

FIG. 10g shows a measured coupling coefficient as a function of frequency between the channels connected to the seventh 114a and eighth 114b transmitter coils.

FIG. 10h shows a measured coupling coefficient as a function of frequency between the channels connected to the seventh 114a and second 112b transmitter coils.

FIG. 10i shows a measured coupling coefficient as a function of frequency between the channels connected to the seventh 114a and third 112c transmitter coils.

FIG. 10j shows a measured coupling coefficient as a function of frequency between the channels connected to the seventh 114a and fourth 112d transmitter coils.

FIG. 10k shows a measured coupling coefficient as a function of frequency between the channels connected to the eighth 114b and third 112c transmitter coils.

FIG. 10l shows a measured coupling coefficient as a function of frequency between the channels connected to the eighth 114b and fourth 112d transmitter coils.

FIG. 10m shows a measured coupling coefficient as a function of frequency between the channels connected to the eighth 114b and fifth 112e transmitter coils.

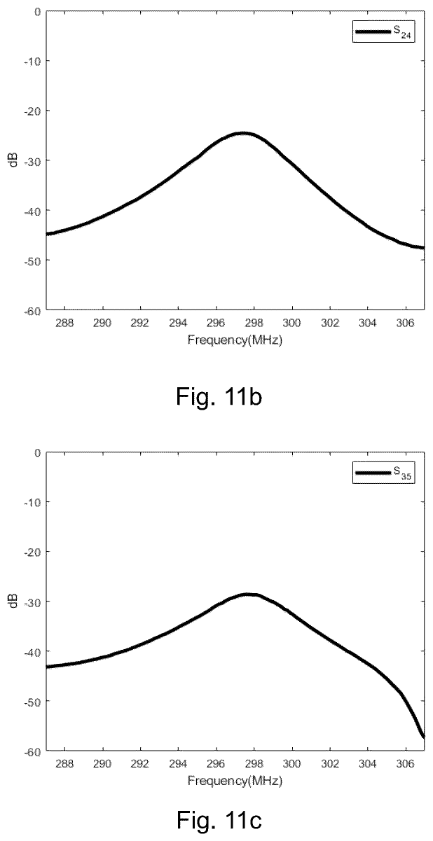

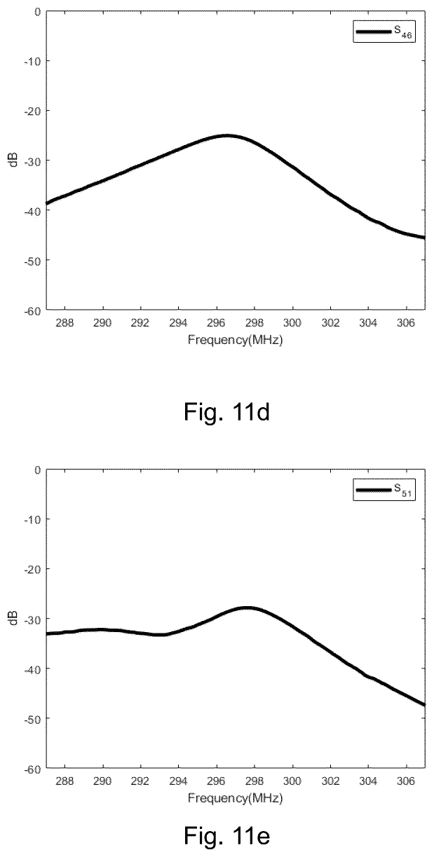

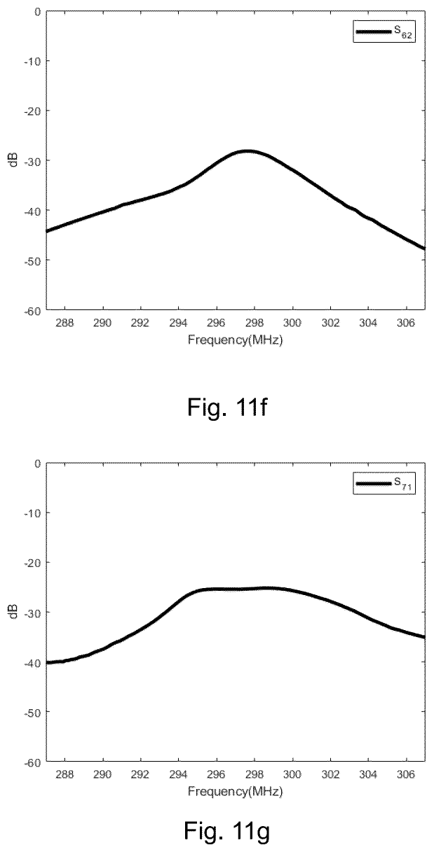

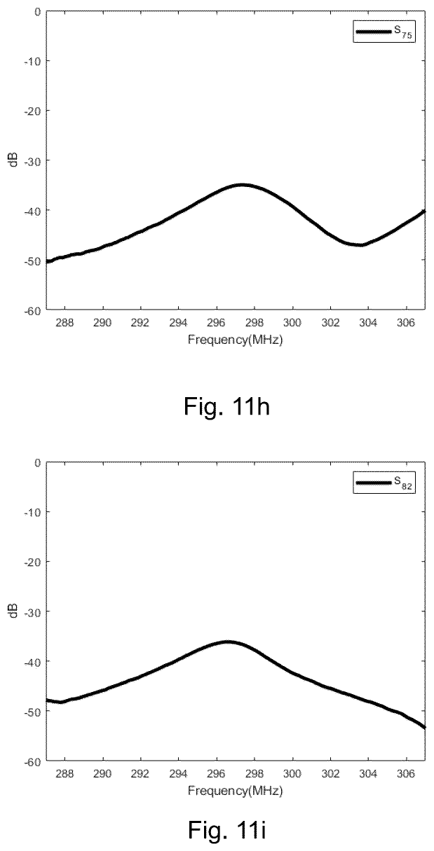

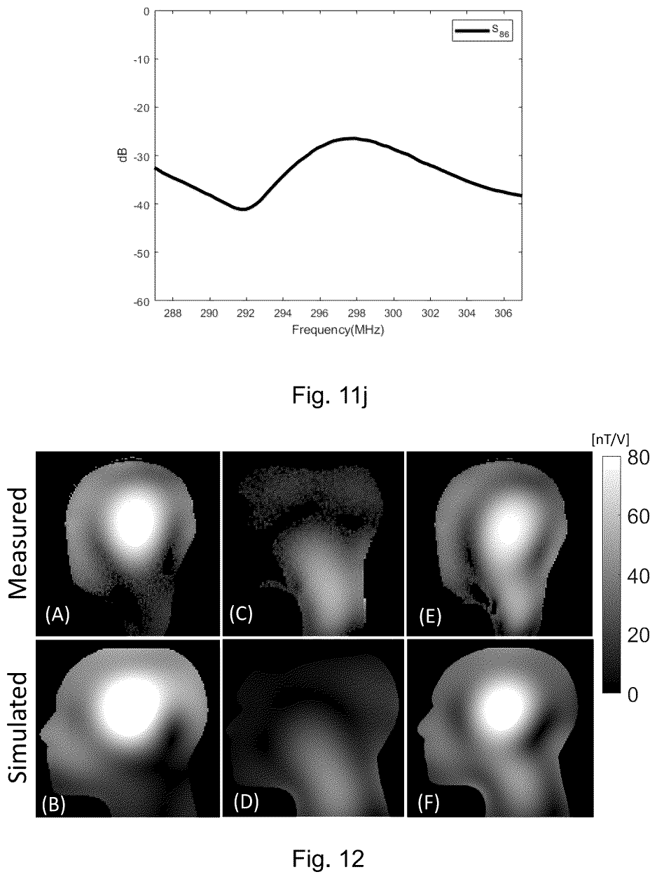

As can be seen from FIGS. 10a-m, the average coupling coefficient between adjacent elements is 24.64 dB, indicating that only 0.35% of the power passing through the coils couples into an adjacent coil. FIG. 11a shows a measured coupling coefficient as a function of frequency between the channels connected to the first 112a and third 112c transmitter coils.

FIG. 11b shows a measured coupling coefficient as a function of frequency between the channels connected to the second 112b and fourth 112d transmitter coils.

FIG. 11c shows a measured coupling coefficient as a function of frequency between the channels connected to the third 112c and fifth 112e transmitter coils.

FIG. 11d shows a measured coupling coefficient as a function of frequency between the channels connected to the fourth 112d and sixth 112f transmitter coils.

FIG. 11e shows a measured coupling coefficient as a function of frequency between the channels connected to the fifth 112e and first 112a transmitter coils.

FIG. 11f shows a measured coupling coefficient as a function of frequency between the channels connected to the sixth 112f and second 112b transmitter coils.

FIG. 11g shows a measured coupling coefficient as a function of frequency between the channels connected to the seventh 114a and first 112a transmitter coils.

FIG. 11h shows a measured coupling coefficient as a function of frequency between the channels connected to the seventh 114a and fifth 112e transmitter coils.

FIG. 11i shows a measured coupling coefficient as a function of frequency between the channels connected to the eighth 114b and second 112b transmitter coils.

FIG. 11j shows a measured coupling coefficient as a function of frequency between the channels connected to the eighth 114b and sixth 112f transmitter coils.

As can be seen from FIGS. 11a-j, the average coupling coefficient as a function of frequency between the second neighbouring elements is −29.4 dB, indicating that just 0.1% of the power passing through a given transmitter coil couples into a second neighbouring element.

Overall therefore, it can be seen that not only is the overwhelming majority of power transmitted to each element successfully coupled into each element, but the extent of coupling between first- and second-neighbouring elements is very low. As such, the performance of the transmitter coil array 110 is both very efficient and extremely reliable.

FIG. 12 shows simulated and measured B₁⁺ maps in a head and shoulder phantom in the sagittal midplane for various operational configurations of the coil array shown in FIG. 8a.

Panels A, C, and E of FIG. 12 show B₁⁺ maps of the measured performance of the transmitter coil array 110 of FIG. 8a using the abovementioned head-shoulder phantom having a relative permittivity, εᵣ, of 52.1, and a conductivity of 0.41 S m⁻¹. The measurements depicted in FIG. 12 and elsewhere were performed on the Magnetom Terra 7 T whole body scanner manufactured by Siemens Healthcare GmbH, Germany.

Panels B, D, and F of FIG. 12 show B₁⁺ maps of the simulated performance of the transmitter coil array 110 of FIG. 8a using the abovementioned head-shoulder phantom having a relative permittivity, εᵣ, of 52.1, and a conductivity of 0.41 S m⁻¹. In the measurements shown in FIG. 12 the simulated peak specific absorption rate for 1 W of input power (in a circularly polarised configuration) in the Duke model is 0.3 W kg⁻¹. The specific absorption rate is determined by averaging the absorption over 10 g mass portions of the Duke model, and therefore may be referred to as the 10 g-peak specific absorption rate. Panels A and B of FIG. 12 respectively show the B₁⁺ maps, in the sagittal midplane, of the measured and simulated performance of the transmitter coil array 110 when only the six transmitter coils 112a-f in the first circumferential row of the transmitter coil array are activated. In other words, panels A and B of FIG. 12 show B₁⁺ maps of the simulated and measured performance of the transmitter coil array 110 for use in obtaining head-only (i.e., brain-only) images of a patient.

As can be clearly seen from panels A and B, activating only the six transmitter coils 112a-f in the first circumferential row of the transmitter coil array 110 enables measurements of the brain of a patient but not the spinal cord.

Panels C and D of FIG. 12 respectively show B₁⁺ maps, in the sagittal midplane, of the measured and simulated performance of the transmitter coil array 110 when only the two transmitter coils 114a-b in the second circumferential row of the transmitter coil array 110 are activated. In other words, panels C and D of FIG. 12 show B₁⁺ maps of the simulated and measured performance of the transmitter coil array 110 for use in obtaining neck-only (i.e., spine-only) images of a patient.

Meanwhile, panels E and F of FIG. 12 respectively show B₁⁺ maps, in the sagittal midplane, of the measured and simulated performance of the transmitter coil array 110 when all eight transmitter coils 112a-f, 114a-b are activated. In other words, panels E and F of FIG. 12 show B₁⁺ maps of the simulated and measured performance of the transmitter coil array 110 for use in obtaining simultaneous brain-cord images.

As can be clearly seen from panels E and F, activating all eight transmitter coils 112a-f, 114a-b in both the first and second circumferential rows of the transmitter coil array 110 enables measurements of the brain and spinal cord of a patient simultaneously. The average magnetic field distribution in the sagittal midplane of the head and shoulder phantom while exciting the top 6 channels and all 8 channels are 37.23 nT/V and 38.34 nT/V, respectively. In other words, the activation of the two transmitter coils in the second circumferential row facilitates measurement in the neck/spine region of the patient whilst barely impacting the field distribution of head/brain measurement carried out by the six transmitter coils in the first circumferential row. The available B₁⁺ is uniformly distributed in the brain or in the brain and C-spine depending on the chosen excitation.

The simulated and measured results shown in FIG. 12 confirm that the proposed eight-coil transmitter/transceiver array 110 extends the field coverage of a coil assembly 100 to also cover the neck region without compromising the field distribution in the head region compared to pre-existing head coils implemented in 7 T MRI machines 200.

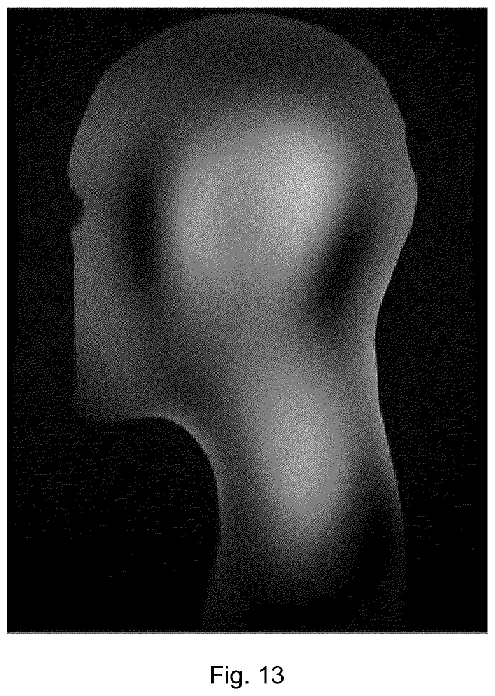

FIG. 13 shows a fast turbo spin echo (TSE) image taken using the transmitter coil array 110 shown in FIG. 8a. The fast TSE image of FIG. 13 has a field-of-view of 255 (axial)×340 (longitudinal) mm² and was collected with an echo time of 67 ms, a repetition time of 9 s, and a total acquisition time of 100 s.

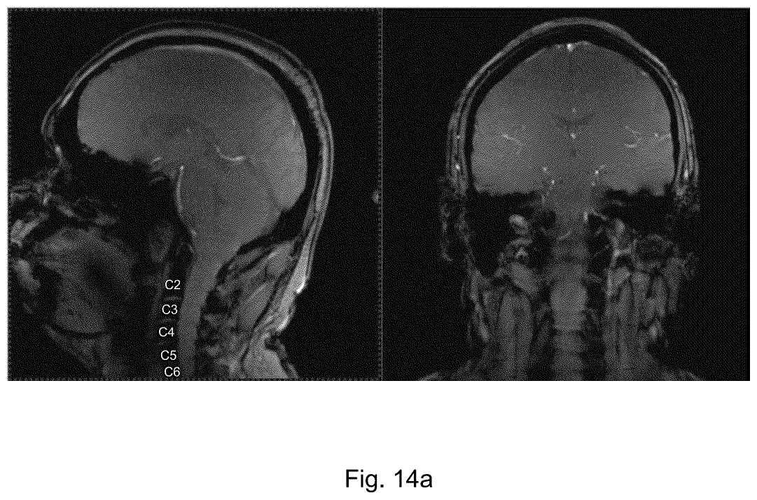

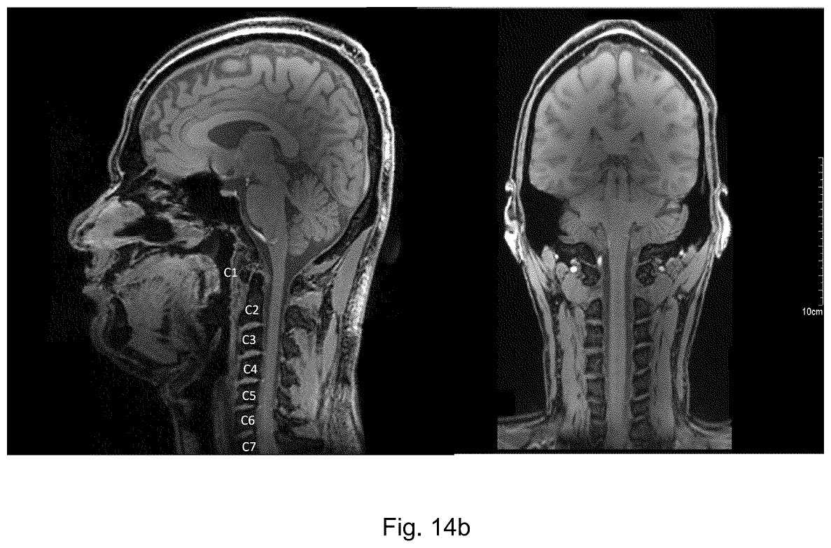

FIG. 14 shows examples of in-vivo magnetic resonance images collected using the transmitter coil array 110 shown in FIG. 8a. FIG. 14b shows examples of in-vivo magnetic resonance image collected using the complete coil assembly 100 shown in FIG. 1b. The images are obtained using an MRI sequence in sagittal and coronal plane.

FIGS. 13, 14a and 14b clearly show the utility of the transmitter coil array 110 shown in FIG. 8a for simultaneous head-coil measurements of patients.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

### REFERENCES

A full citation for the publication cited above to more fully describe and disclose the invention and the state of the art to which the invention pertains are provided below. The entirety of this reference is incorporated herein.

Christ A., Kainz W., Hahn E. G., Honegger K., Zefferer M., Neufeld E., Rascher W., Janka R., Bautz W., Chen J., Kiefer B., Schmitt P., Hollenbach H. P., Shen J. X., Oberle M., and Kuster N., “The Virtual Family—Development of Anatomical CAD Models of two Adults and two Children for Dosimetric Simulations”, Phys. Med. Bio., 55, N23-N38, 2010.

1. A coil array for use with a neurovascular magnetic resonance imaging apparatus that is operable with a permanent magnetic field of 7T, the coil array comprising no more than eight transmitter coils disposed on a cylindrical support extending around a central axis,
wherein the transmitter coils comprise a first coil set arranged in a first circumferential row and a second coil set arranged in a second circumferential row, and
wherein the first circumferential row is offset from the second circumferential row in a longitudinal direction that runs parallel to the central axis, whereby the first coil set and the second coil set are suitable for alignment respectively with a head and neck of a patient.

2. The coil array according to claim 1, wherein six transmitter coils are arranged in the first circumferential row, and two transmitter coils are arranged in the second circumferential row.

3. The coil array according to claim 1, wherein the first circumferential row overlaps the second circumferential row in the longitudinal direction.

4. The coil array according to preceding claim 1, wherein the first coil set fully encircles the central axis.

5. The coil array according to claim 1, wherein the first coil set comprises a plurality of the transmitter coils in an arrangement that exhibits rotational symmetry around the central axis.

6. The coil array according to claim 1, wherein adjacent transmitter coils in the first coil set do not overlap with one another.

7. The coil array according to claim 1, wherein the second coil set partially encircles the central axis.

8. The coil array according to claim 7, wherein the second coil set defines an approximately semi-circular arc around the central axis.

9. The coil array according to claim 1, wherein the second coil set comprises a plurality of the transmitter coils arranged symmetrically about a longitudinal plane that bisects the first and second circumferential rows.

10. The coil array according to claim 7, wherein adjacent transmitter coils in the second coil set do not overlap with one another.

11. The coil array according to claim 1 wherein one or more of the transmitter coils are transceiver coils.

12. A coil assembly for use with a magnetic resonance imaging apparatus that is operable with a permanent magnetic field of 7T, the coil assembly comprising:
a transmitter coil array claim; and
a receiver coil array,
wherein the transmitter coil array comprises no more than eight transmitter coils disposed on a cylindrical support extending around a central axis,
wherein the transmitter coils comprise a first coil set arranged in a first circumferential row and a second coil set arranged in a second circumferential row, and
wherein the first circumferential row is offset from the second circumferential row in a longitudinal direction that runs parallel to the central axis, whereby the first coil set and the second coil set are suitable for alignment respectively with a head and neck of a patient.

13. The coil assembly according to claim 12, wherein the transmitter coil array is enclosed between coaxial inner and outer walls.

14. The coil assembly according to claim 13, further comprising a radio-frequency shield disposed on an inner surface of the outer wall.

15. The coil assembly according to claim 12, wherein the receiver coil array comprises a first receiver coil set arranged in a posterior section of the receiver coil array and a second receiver coil set arranged in an anterior section of the receiver coil array.

16. The coil assembly according to claim 15, wherein the first receiver coil set comprises 40 receiver coils, and the second receiver coil set comprises 16 receiver coils.

17. The coil assembly according to claim 16, wherein the transmitter coils of the transmitter coil array are transceiver coils.

18. A magnetic resonance imaging apparatus that is operable with a permanent magnetic field of 7T, said apparatus comprising a coil assembly comprising:
a transmitter coil array; and
a receiver coil array,
wherein the transmitter coil array comprises no more than eight transmitter coils disposed on a cylindrical support extending around a central axis,
wherein the transmitter coils comprise a first coil set arranged in a first circumferential row and a second coil set arranged in a second circumferential row, and
wherein the first circumferential row is offset from the second circumferential row in a longitudinal direction that runs parallel to the central axis, whereby the first coil set and the second coil set are suitable for alignment respectively with a head and neck of a patient.

19. The magnetic resonance imaging apparatus according to claim 18, wherein the coil assembly is removably connectable therewith.

20. The magnetic resonance imaging apparatus according to claim 18 further comprising a controller configured to selectively activate each transmitter coil of the transmitter coil array of the coil assembly in series or parallel modes.
